(19) United States
(12) Patent Application Publication
(10) Pub. No.: US 2024/0154431 A1
(43) Pub. Date: May 9, 2024

(54) CHARGING MANAGEMENT METHOD AND APPARATUS FOR MULTIPLE BATTERY PACKS, AND ENERGY STORAGE DEVICE

(71) Applicant: ECOFLOW INC., Shenzhen (CN)

(72) Inventors: Lei WANG, Shenzhen (CN); Yunhui XING, Shenzhen (CN)

(21) Appl. No.: 18/415,945

(22) Filed: Jan. 18, 2024

Related U.S. Application Data
(63) Continuation of application No. PCT/CN2022/106937, filed on Jul. 21, 2022.

(30) Foreign Application Priority Data
Jul. 22, 2021 (CN) 202110833046.1

(51) Int. Cl. H02J 7/00; G01R 31/388

(52) U.S. Cl. CPC H02J 7/0014; G01R 31/388; H02J 7/0029; H02J 7/0048; H02J 7/0063; H02J 7/00712; H02J 7/007194

(57) ABSTRACT

A charging management method for multiple battery packs comprises determining a target charging current of each battery pack according to a sampled temperature of each battery pack and a sampled voltage of each battery pack; calculating a difference between the sum of the target charging currents of various battery packs and the sum of sampled charging currents of the various battery packs, to obtain a total PI adjustment value; sending the total PI adjustment value to a charging device, to enable the charging device to adjust a total charging current according to the total PI adjustment value; determining a charging current of each battery pack according to the sampled charging current of each battery pack and the total charging current, and determining a charging voltage of each battery pack according to the sampled voltage of each battery pack.

### CROSS-REFERENCE TO RELATED APPLICATIONS

This application is a continuation application of PCT patent application No. PCT/CN2022/106937, filed on Jul. 21, 2022, which claims priority to Chinese Patent Application No. 2021108330461, filed on Jul. 22, 2021, all of which is incorporated herein by reference in their entirety.

### TECHNICAL FIELD

The present application relates to the field of charging of battery packs, and particularly, to a charging management method and apparatus for multiple battery packs, and an energy storage device.

### BACKGROUND

The description here merely provides background information related to the present application and does not necessarily constitute the prior art.

When multiple battery packs are charged by a charging device, the battery packs do not interact with the charging device, and the charging device merely outputs a constant charging voltage and a constant charging current. At this time, if the charging current and the charging voltage are too large, the battery pack may explode due to over-current or over-voltage, causing electric accidents. However, if the charging current and the charging voltage are too small, the maximum performance of the charging device cannot be fully used, resulting in a slow charging speed and long charging time.

### SUMMARY

According to various embodiments of the present application, a charging management method and apparatus for multiple battery packs, an energy storage device and a readable storage medium are provided.

The present disclosure provides a charging management method for multiple battery packs. The method includes:
acquiring sampled temperatures, sampled voltages and sampled charging currents of various battery packs;
determining a target charging current of each battery pack according to the sampled temperature of each battery pack and the sampled voltage of each battery pack;
calculating a difference between the sum of the target charging currents of the various battery packs and the sum of the sampled charging currents of the various battery packs, to obtain a total PI adjustment value;
sending the total PI adjustment value to a charging device, to enable the charging device to adjust a total charging current according to the total PI adjustment value; and
receiving the total charging current, determining a charging current of each battery pack according to the sampled charging current of each battery pack and the total charging current, and determining a charging voltage of each battery pack according to the sampled voltage of each battery pack.

The present disclosure further provides a charging management apparatus for multiple battery packs. The apparatus includes:
an acquisition module, configured to acquire sampled temperatures, sampled voltages and sampled charging currents of various battery packs;
a determination module, configured to determine a target charging current of each battery pack according to the sampled temperature of each battery pack and the sampled voltage of each battery pack;
a calculation module, configured to calculate a total PI adjustment value according to the target charging currents and the sampled charging currents of the various battery packs;
a sending module, configured to send the total PI adjustment value to a charging device, to enable the charging device to adjust a total charging current according to the total PI adjustment value; and
a charging module, configured to receive the total charging current, determine a charging current of each battery pack according to the sampled charging current of each battery pack and the total charging current, and determine a charging voltage of each battery pack according to the sampled voltage of each battery pack.

The present application provides an energy storage device, which includes a storage and one or more processors, where the storage stores a computer program thereon, and the computer program, when being executed, causes the one or more processors to implement the charging management method for the multiple battery packs according to the present application.

The present application provides a readable storage medium, storing a computer program, where the computer program, when being executed, cause one or more processor to implement the charging management method for multiple battery packs according to the present application.

Details of one or more embodiments according to the present application are provided in the accompanying drawings and descriptions below. Other features, objectives, and advantages of the present application will become apparent from the specification, the drawings, and the claims.

### BRIEF DESCRIPTION OF THE DRAWINGS

To describe the technical solutions in the embodiments of the present application more clearly, the drawings needed to be used in the embodiments of the present application will be described briefly below. It should be understood that the drawings merely show some embodiments of the present application, and thus should not be regarded as limitations on the scope of protection of the present application. In the drawings, similar parts are represented by similar numerals.

FIG. 1 schematically shows a flow chart of a charging management method for multiple battery packs provided in an embodiment of the present application.

FIG. 2 schematically shows a flow chart of a process for acquiring sampled temperatures of various battery packs in a charging management method for multiple battery packs provided in an embodiment of the present application.

FIG. 3 schematically shows a flow chart of a process for determining a target charging current of each battery pack in a charging management method for multiple battery packs provided in an embodiment of the present application.

FIG. 4 schematically shows a principle of PI adjustment provided in an embodiment of the present application.

FIG. 5 schematically shows a flow chart of a process for determining a charging current of each battery pack in a charging management method for multiple battery packs provided in an embodiment of the present application.

FIG. 6 schematically shows a flow chart of another process for determining a charging current of each battery pack in a charging management method for multiple battery packs provided in an embodiment of the present application.

FIG. 7 schematically shows a flow chart of a process for determining a charging voltage of each battery pack in a charging management method for multiple battery packs provided in an embodiment of the present application.

FIG. 8 shows a charging management system for multiple battery packs provided in an embodiment of the present application.

FIG. 9 schematically shows a flow chart of another charging management method for multiple battery packs provided in an embodiment of the present application.

FIG. 10 shows another charging management system for multiple battery packs provided in an embodiment of the present application.

FIG. 11 shows a schematic structural view of a charging management apparatus for multiple battery packs provided in an embodiment of the present application.

List of numerals: 10—charging management apparatus for battery packs; 11—acquisition module; 12—determination module; 13—calculation module; 14—sending module; 15—charging module.

### DETAILED DESCRIPTION

The technical solutions according to the embodiments of the present application will be described clearly and fully below with reference to the accompanying drawings in the embodiments of the present application. Apparently, the embodiments described are merely some, but not all of the embodiments of the present application.

Generally, the components of the embodiments of the present application described and illustrated in the drawings herein can be arranged and designed in various different configurations. Therefore, the following detailed description of the embodiments of the present application provided in connection with the accompanying drawings is not intended to limit the scope of the claimed application, but merely represents selected embodiments of the present application. All other embodiments obtained by a person of skill in the art without creative efforts based on the embodiments of the present application shall fall within the protection scope of the present application.

Hereinafter, as used in various embodiments of the present application, the terms “include”, “have” and derivatives thereof are only intended to indicate specific features, values, steps, operations, elements, components, or combinations thereof, and should not be construed as excluding the presence of one or more other features, values, steps, operations, elements, components, or combinations thereof, or the possibility of adding one or more other features, values, steps, operations, elements, components, or combinations thereof.

In addition, the terms “first”, “second”, and “third” are only used for distinguishing description, and cannot be interpreted as indicating or implying relative importance.

Unless otherwise defined, all terms (including technical and scientific terms) used herein have the same meaning as commonly understood by one of ordinary skill in the art to which embodiments of the present application belongs. The terms (such as those defined in commonly used dictionaries) will be interpreted as having the same meaning as the contextual meaning in related art and will not be interpreted as having an idealistic meaning or an overly formal meaning, unless clearly defined in various embodiments of the present application.

The embodiment provided in the present application is suitable for use in an energy storage device including battery modules. The battery module includes several cells that are connected in series or in parallel to form a battery pack, and several battery packs are connected in series or in parallel to form the battery module. The battery module is provided with an interface through which the battery module outputs current or receives current for being charged. In other embodiments, the battery module of the energy storage device may include a single cell or a plurality of cells. Each cell can discharge or receive current for being charged independently or in combination with other cells. In other embodiments, the battery module of the energy storage device includes several cells that are connected in series or in parallel to form a battery pack. Each battery pack can discharge or receive current for being charged independently or in combination with other battery packs.

The charging management method for multiple battery packs provided in the present application is suitable for use in an energy storage device including several battery packs, and also in an energy storage device including only several cells. Hereinafter, the charging management method for multiple battery packs provided in the present application will be further explained by way of examples where multiple battery packs are charged.

According to the charging management method for multiple battery packs disclosed in the present application, when multiple battery packs are charged, if the multiple battery packs include a master battery pack, the master battery pack can be configured to acquire sampled temperatures, sampled voltages and sampled charging currents of various battery packs; determine a target charging current of each battery pack according to the sampled temperature of each battery pack and the sampled voltage of each battery pack; calculate a difference between the sum of the target charging currents of the various battery packs and the sum of the sampled charging currents of the various battery packs, to obtain a total PI adjustment value; send the total PI adjustment value to a charging device, to enable the charging device to adjust a total charging current according to the total PI adjustment value; and receive the total charging current, determine a charging current of each battery pack according to the sampled charging current of each battery pack and the total charging current, and determine a charging voltage of each battery pack according to the sampled voltage of each battery pack. In the present application, the sampled temperatures, sampled voltages and sampled charging currents of various battery packs are acquired by the master battery pack, and the output of the charging device is controlled by using the sampled temperatures, sampled voltages and sampled charging currents of the various battery packs, so that the maximum performance of the charging device is fully utilized while ensuring the electrical safety, to improve the charging efficiency and shorten the charging time.

It can be understood that when multiple battery packs are charged, if the multiple battery packs do not include a master battery pack, the multiple battery packs can be connected to an intermediate controller, and the intermediate controller is used to implement the charging management method for multiple battery packs. Sampled temperatures, sampled voltages and sampled charging currents of various battery packs are acquired by the intermediate controller, and the output of the charging device is controlled by using the sampled temperatures, sampled voltages and sampled charging currents of the various battery packs, so that the maximum performance of the charging device is fully utilized while ensuring the electrical safety, to improve the charging efficiency and shorten the charging time.

In an embodiment of the present disclosure, as shown in FIG. 1, a charging management method for multiple battery packs is provided, which includes Steps S100, S200, S300, S400 and S500.

S100: Sampled temperatures, sampled voltages and sampled charging currents of various battery packs are acquired.

In the charging and discharging process of a battery pack, heat accumulation will occur in the battery pack, causing the temperature rise of the battery pack. Only a short time is spent from the temperature rise to flame of the battery pack due to thermal runaway, and fire tends to occur, causing personnel injuries and property losses. If the battery pack is constantly charged with a large charging current or a high charging voltage, the battery pack will be retained in a high-temperature state for a long time, which is likely to cause flame of the battery pack.

To overcome the above problems, a voltage determination element can be used to acquire the battery pack voltage, and a temperature sensor is used to acquire a current battery pack temperature. A current target charging current of the battery pack is determined by using the battery pack temperature and the battery pack voltage, to avoid a too large charging current of the battery pack, effectively reduce flame of the battery pack, and ensure the electrical safety.

Exemplarily, each battery pack at least includes a temperature sensor, a voltage sensor and a current sensor. The temperature sensor is configured to collect the battery core temperature of the battery pack in the charging process in real time (the battery core temperature collected in real time is recorded as the sampled temperature in the present application). The voltage sensor is configured to collect the battery voltage of the battery pack in the charging process in real time (the battery voltage collected in real time is recorded as the sampled voltage in the present application). The current sensor is configured to collect the charging current of the battery pack in the charging process in real time (the charging current collected in real time is recorded as the sampled charging current in the present application).

Further, considering that there may be a deviation in the measurement of the battery core temperature at a single point, when the battery core temperature of the battery pack is determined in the present application, temperature sensors are mounted at multiple preset locations of each battery pack. Multiple battery core temperatures are acquired by the temperature sensors, and the sampled temperature of a corresponding battery pack is determined according to a mean of the battery cell temperatures at the preset multiple locations. Through multi-point measurement, the deviation in temperature acquisition is reduced, so that the sampled temperature of each battery pack is close to the actual temperature of the battery core.

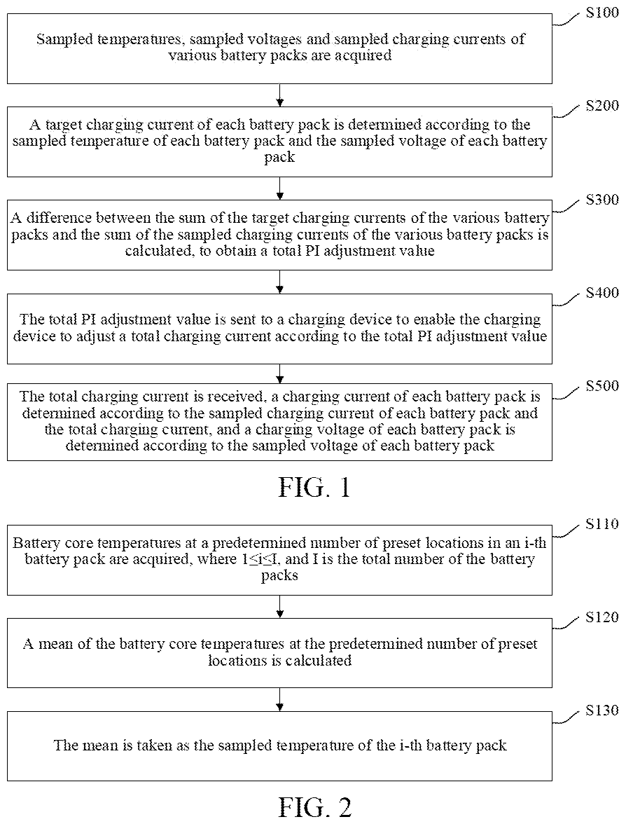

Exemplarily, as shown in FIG. 2, the step of acquiring sampled temperatures of various battery packs in Step S100 includes Steps S110-S130.

S110: Battery core temperatures at a predetermined number of preset locations in an i-th battery pack are acquired, where 1≤i≤I, and I is the total number of the battery packs.

S120: A mean of the battery core temperatures at the predetermined number of preset locations is calculated.

S130: The mean is taken as the sampled temperature of the i-th battery pack.

It can be understood that when the sampled temperatures of the various battery packs are acquired, Steps S110, S120 and S130 can be performed once sequentially to determine the sampled temperature of one battery pack, and then further performed once sequentially to determine the sampled temperature of another battery pack, until the sampled temperatures of all the battery packs are determined. Alternatively, Step S110 is performed I times, then Step S120 is performed I times, and finally Step S130 is performed I times to determine the sampled temperatures of all the battery packs.

S200: A target charging current of each battery pack is determined according to the sampled temperature of each battery pack and the sampled voltage of each battery pack.

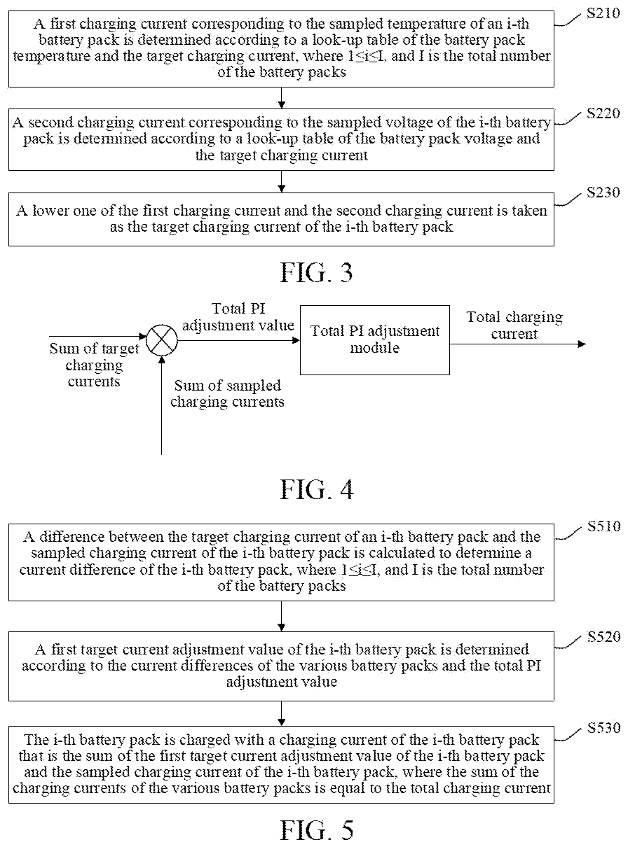

Exemplarily, as shown in FIG. 3, Step S200 may include Steps S210-S230.

S210: A first charging current corresponding to the sampled temperature of an i-th battery pack is determined according to a look-up table of the battery pack temperature and the target charging current, where 1≤i≤I, and I is the total number of the battery packs.

S220: A second charging current corresponding to the sampled voltage of the i-th battery pack is determined according to a look-up table of the battery pack voltage and the target charging current.

S230: A lower one of the first charging current and the second charging current is taken as the target charging current of the i-th battery pack.

It can be understood that when the target charging current of each battery pack is determined, Steps S210, S220 and S230 can be performed once sequentially to determine the target charging current of one battery pack, and then further performed once sequentially to determine the target charging current of another battery pack, until the target charging currents of all the battery packs are determined. Alternatively, Step S210 is performed I times, then Step S220 is performed I times, and finally Step S230 is performed I times to determine the target charging currents of all the battery packs.

It can be understood that by taking a lower one of the first charging current and the second charging current as the target charging current, and charging the battery pack with the target charging current, the fire caused by over-voltage in the charging process of the battery pack can be avoided and the fire caused by overheating in the charging process of the battery pack can also be avoided, so as to ensure electrical safety while ensuring high efficiency charging.

It can be understood that the look-up table of the battery pack temperature and the target charging current and the look-up table of the battery pack voltage and the target charging current can be the standard look-up tables in the industry, or look-up tables obtained by pre-testing the performance of different electrical products.

S300: A difference between the sum of the target charging currents of the various battery packs and the sum of the sampled charging currents of the various battery packs is calculated, to obtain a total PI adjustment value.

Exemplarily, if a battery pack A and a battery pack B are charged at the same time, the target currents of the battery pack A and the battery pack B are 10 A respectively, then the total target current is 20 A; and the sampled charging currents of the battery pack A and the battery pack B are respectively 9A, then the total sampled charging current is 18 A. Then, the total PI adjustment value can be determined by a formula for calculating the total PI adjustment value. That is, the total PI adjustment value can be determined by a formula below:
total PI adjustment value=K* difference, in which: K is a proportional coefficient, which can be set according to the actual adjustment needs; and the difference is the difference between the total target current and the total sampled charging current. When the total target current is greater than the total sampled charging current, the difference is positive, and correspondingly the total PI adjustment value is also positive. When the total target current is less than the total sampled charging current, the difference is negative, and correspondingly the total PI adjustment value is also negative.

In this embodiment, for example, the total PI adjustment value is positive; however, in practical use, the total PI adjustment value can be negative. That is, when the charging current of each battery pack in the energy storage device is too large, the charging current of each battery pack needs to be lowered, and the total PI adjustment value at this time is negative. In other embodiments, the PI adjustment value may be 0. For example, in the energy storage device, the battery pack A has a target charging current of 10 A and a sampled current of 9 A, and the battery pack B has a target charging current of 10 A and a sampled current of 11 A, then the total target charging current is 20 A, the total sampled charging current is 20 A, and the total PI adjustment value at this time is 0.

As can be seen from the above, the total PI adjustment value is dynamic, and the total PI adjustment value changes with varying difference between the sum of the target charging currents of the various battery packs and the sum of the sampled charging currents of the various battery packs.

S400: The total PI adjustment value is sent to a charging device, to enable the charging device to adjust a total charging current according to the total PI adjustment value.

Exemplarily, as shown in FIG. 4, the total charging current output by the charging device can be adjusted by using a PI adjustment function of a total PI adjustment module, that is, by using the total PI adjustment value, such that the total charging current output by the charging device is close to the sum of the target charging currents of the various battery packs. It can be understood that the PI adjustment process is very fast and stable, which can effectively ensure that the total charging current output by the charging device quickly reaches the sum of the target charging currents of the various battery packs. The process during which the total charging current output by the charging device quickly reaches the sum of the target charging currents of the various battery packs is very stable, thus avoiding the interference to the charging process by the sudden change of the total charging current output by the charging device. It is to be noted that the PI adjustment in this embodiment is a broad-sense PI adjustment. For example, the total PI adjustment value can be determined by a proportional (P)—integral (I) adjuster, or the total PI adjustment value can be determined by a proportional (P) adjuster, which can be set specifically according to actual needs.

S500: The total charging current is received, a charging current of each battery pack is determined according to the sampled charging current of each battery pack and the total charging current, and a charging voltage of each battery pack is determined according to the sampled voltage of each battery pack.

Exemplarily, as shown in FIG. 5, the step of determining a charging current of each battery pack according to the sampled charging current of each battery pack and the total charging current in Step S500 includes Steps S510-S530.

S510: A difference between the target charging current of an i-th battery pack and the sampled charging current of the i-th battery pack is calculated to determine a current difference of the i-th battery pack, where 1≤i≤I, and I is the total number of the battery packs.

Step S510 is performed I times to obtain I current differences of I battery packs.

S520: A first target current adjustment value of the i-th battery pack is determined according to the current differences of the various battery packs and the total PI adjustment value.

Exemplarily, the first target current adjustment value M i of the i-th battery pack can be determined by a formula below:

$$Δ {I}_{i} = \frac{current difference of i - th battery pack}{current differences of various battery packs} * total PI adjustment value .$$

It can be understood that the sum of the first target current adjustment values of the various battery packs is the total PI adjustment value. The larger the current difference of the battery pack is, the larger the corresponding first target current adjustment value will be. The PI adjustment of the charging current of the battery pack is carried out by using the first target current adjustment value of each battery pack, thus ensuring that when the current difference of the battery pack is larger, the sampled charging current of the battery pack can be quickly adjusted to approach the corresponding target charging current by using the larger first target current adjustment value.

S530: The i-th battery pack is charged with a charging current of the i-th battery pack that is the sum of the first target current adjustment value of the i-th battery pack and the sampled charging current of the i-th battery pack, where the sum of the charging currents of the various battery packs is equal to the total charging current.

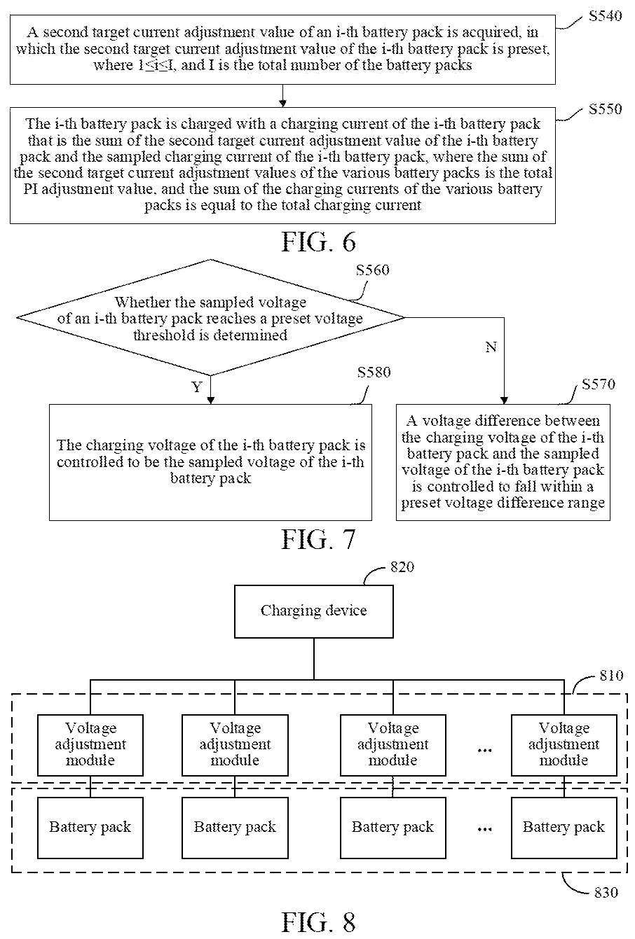

Exemplarily, as shown in FIG. 6, Steps S510-S530 can be replaced by Steps S540 and S550 below.

S540: A second target current adjustment value of an i-th battery pack is acquired, in which the second target current adjustment value of the i-th battery pack is preset, where 1≤i≤I, and I is the total number of the battery packs.

Each PI adjustment of each battery pack has a fixed value. For example, each charging current adjustment of the battery pack is preset to 0.5 A, and 0.5 A is the second target current adjustment value corresponding to the battery pack. When the charging current of the battery pack reaches the target charging current, the second target current adjustment value of the battery pack is 0 A.

S550: The i-th battery pack is charged with a charging current of the i-th battery pack that is the sum of the second target current adjustment value of the i-th battery pack and the sampled charging current of the i-th battery pack, where the sum of the second target current adjustment values of the various battery packs is the total PI adjustment value, and the sum of the charging currents of the various battery packs is equal to the total charging current.

It can be understood that the PI adjustment of the charging current of each battery pack is carried out by using the second target current adjustment value of each battery pack, to ensure that the sampled charging current of the battery pack can approach the corresponding target charging current quickly and stably. This enables each battery pack to obtain the corresponding target charging current to charge itself, thereby realizing efficient and safe charging of each battery pack. It is to be noted that if the total PI adjustment value is 0, the charging current from the charging device is not adjusted, and the corresponding adjustment will be made according to the sampled current of each battery pack, that is, the adjustment will be made according to Steps S540 and S550. Each battery pack is adjusted according to the preset PI adjustment value. For example, the battery pack A has a sampled charging current of 9 A and a target charging current of 10 A, and the battery pack B has a sampled charging current of 11 A and a target charging current of 10 A. In this embodiment, the PI adjustment values of the battery pack A and the battery pack B can both be set to 0.5 A. When the charging device outputs a charging current of 20 A, the charging current of the battery pack A becomes 9.5 A, and the charging current of the battery pack B becomes 10.5 A. Because the process of PI adjustment is fast and stable, the charging current of each battery pack can be quickly adjusted to the corresponding target charging current to ensure the charging safety.

Exemplarily, as shown in FIG. 7, the step of determining a charging voltage of each battery pack according to the sampled voltage of each battery pack in Step S500 includes Steps S560-S580.

S560: Whether the sampled voltage of an i-th battery pack reaches a preset voltage threshold is determined,

where 1≤i≤I, and I is the total number of the battery packs. When the sampled voltage of the i-th battery pack does not reach the voltage threshold, Step S570 is performed; and when the sampled voltage of the i-th battery pack reaches the voltage threshold, Step S580 is performed.

S570: a voltage difference between the charging voltage of the i-th battery pack and the sampled voltage of the i-th battery pack is controlled to fall within a preset voltage difference range.

S580: The charging voltage of the i-th battery pack is controlled to be the sampled voltage of the i-th battery pack.

It can be understood that if the sampled voltage of the i-th battery pack does not reach the preset voltage threshold, it means that the i-th battery pack is not fully charged. Then a voltage difference between the charging voltage of the i-th battery pack and the sampled voltage of the i-th battery pack can be controlled to fall within a preset voltage difference range. For example, the range of the preset voltage adjustment value can be 0.8V to 1.2V. That is, there is a voltage difference between the charging voltage input by the charging device to the i-th battery pack and the sampled voltage of the i-th battery pack, so as to ensure that the i-th battery pack is charged at a stabilized voltage. If the sampled voltage of the i-th battery pack reaches the preset voltage threshold, it means that the i-th battery pack is fully charged. To avoid the explosion accident caused by over-voltage of the i-th battery pack, the charging voltage of the i-th battery pack is controlled to be the sampled voltage of the i-th battery pack. That is, the difference between the charging voltage input by the charging device to the i-th battery pack and the sampled voltage of the i-th battery pack is equal to 0, so that the i-th battery pack stops charging.

It can be understood that to control the charging voltages input by the charging device to various battery pack, a voltage adjustment module can be added between each battery pack and the charging device, to control the charging voltage input by the charging device to a corresponding battery pack by the voltage adjustment module connected to each battery pack.

It can be understood that a charging management system for multiple battery packs corresponding to this embodiment is as shown in FIG. 8. The charging management system for multiple battery packs includes voltage adjustment modules 810. The voltage adjustment module 810 is respectively connected to the charging device 820 and the battery pack 830. The voltage adjustment module 810 corresponds one-to-one with the battery pack 830. That is, one voltage adjustment module 810 is connected with one battery pack 830, and each battery pack 830 is connected to one voltage adjustment module 810. The voltage adjustment module 810 controls the charging voltage input by the charging device to the corresponding battery pack 830.

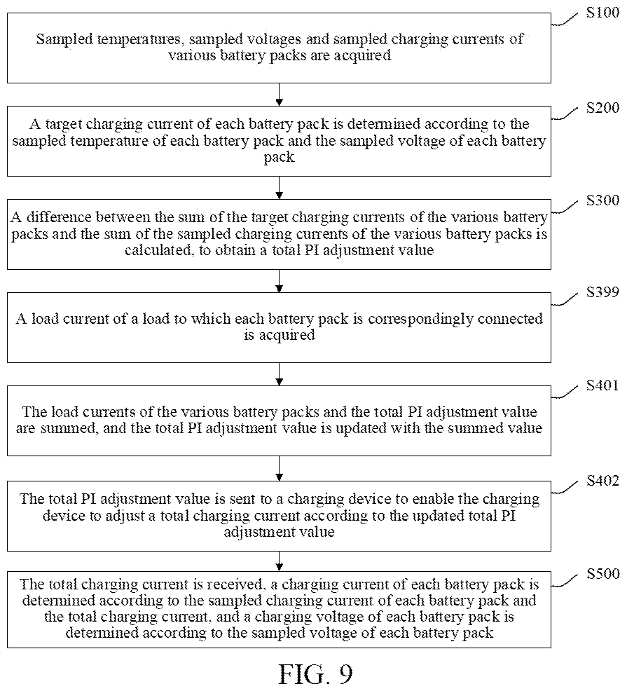

In another embodiment of the present application, as shown in FIG. 9, another charging management method for multiple battery packs is provided. Compared with the above-mentioned embodiments, the charging management method for multiple battery packs provided in this embodiment further includes Step S399 before Step S400, and after Step S399 is added, Step S400 is replaced by Steps S401 and S402. Exemplarily, another charging management method for multiple battery packs includes the following steps:

S100: Sampled temperatures, sampled voltages and sampled charging currents of various battery packs are acquired.

S200: A target charging current of each battery pack is determined according to the sampled temperature of each battery pack and the sampled voltage of each battery pack.

S300: A difference between the sum of the target charging currents of the various battery packs and the sum of the sampled charging currents of the various battery packs is calculated, to obtain a total PI adjustment value.

S399: A load current of a load to which each battery pack is correspondingly connected is acquired.

S401: The load currents of the various battery packs and the total PI adjustment value are summed, and the total PI adjustment value is updated with the summed value.

S402: The updated total PI adjustment value is sent to the charging device, to enable the charging device to adjust a total charging current according to the total PI adjustment value.

S500: The total charging current is received, a charging current of each battery pack is determined according to the sampled charging current of each battery pack and the total charging current, and a charging voltage of each battery pack is determined according to the sampled voltage of each battery pack.

According to the working principle of the battery pack, when the battery pack is in a charging state, a load connected to the battery pack can directly obtain electric energy from the charging device through the connected battery pack, and work normally using the electric energy provided by the charging device. According to the above principle, when multiple battery packs are charged in this embodiment, if some battery packs in the multiple battery packs are connected with loads, a load current of a load to which each battery pack is correspondingly connected is acquired. The load currents of the various battery packs and the total PI adjustment value are summed, and the total PI adjustment value is updated with the summed value. The updated total PI adjustment value is sent to the charging device, to enable the charging device to adjust a total charging current according to the updated total PI adjustment value. In this embodiment, when efficient and safe charging of multiple battery packs are realized, the normal work of the load connected to the battery pack is ensured, and the load working normally does not affect the charging process of the multiple battery packs, so that the efficient and safe charging can still be maintained when the battery pack is connected with a load. It is to be noted that the load currents of the various battery packs and the total PI adjustment value are summed, the total PI adjustment value is updated with the summed value, and the total PI adjustment value of updated values is sent to the charging device. After the charging device adjusts the input charging current according to the total PI adjustment value of updated values, the charging current will be divided into two parts, one part will directly power the load, and the other part will charge the battery pack. Particularly, the total PI adjustment value before value updation is called the first total PI adjustment value, and the total PI adjustment value of updated value is called the second total PI adjustment value, which are used to further explain this embodiment. If a battery pack A and a battery pack B are charged at the same time, the target currents of the battery pack A and the battery pack B are 10 A respectively, then the total target current is 20 A; and the sampled charging currents of the battery pack A and the battery pack B are respectively 9A, then the total sampled charging current is 18 A. If the first total PI adjustment value is determined to be 1A, and the battery pack A is connected to a load having a current demand (called load current in the present application of 5A at this time, then the second total PI adjustment value=first total PI adjustment value+5 A, that is, the total PI adjustment value is 6 A. After the second total PI adjustment value of 6 A is sent to the charging device, the charging current output by the charging device is 24 A. In the charging current of 24 A, a current of 5 A will be used to directly power the load, and the remaining current of 19 A will charge the battery pack A and the battery pack B respectively according to the distribution method in other embodiments mentioned above. In specific embodiments, directly powering the load with a part of the charging current output by the charging device is implemented as follows. When the battery pack A is connected to a load and not being charged, the battery pack A outputs a current to power the load. When the battery pack A is connected to a load and being charged, an input interface of the battery pack A receives the charging current, a part of the charging current will flow directly to the load and the other part will flow to the battery pack A.

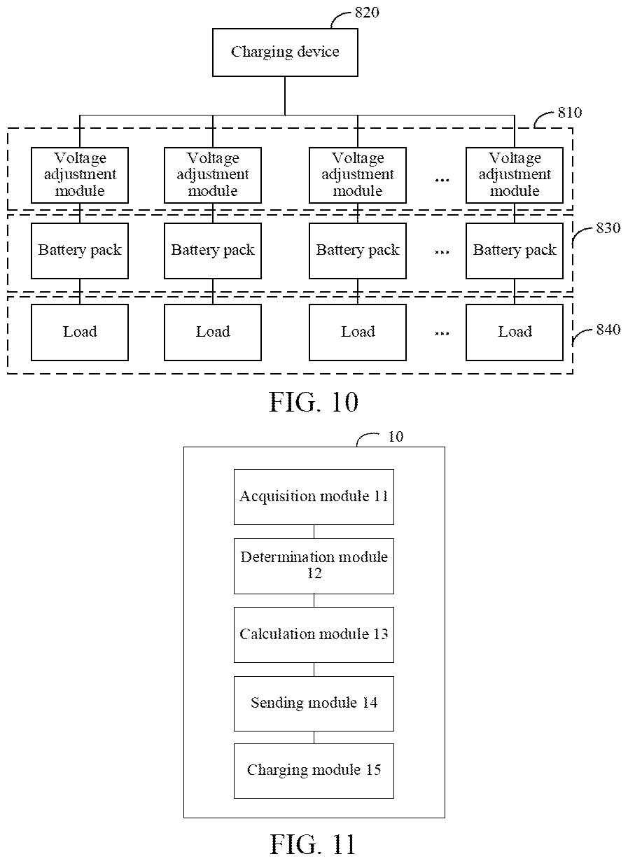

It can be understood that a charging management system for multiple battery packs corresponding to this embodiment is as shown in FIG. 10. The charging management system for multiple battery packs includes voltage adjustment modules 810. The voltage adjustment module 810 is respectively connected to the charging device 820 and the battery pack 830. The voltage adjustment module 810 corresponds one-to-one with the battery pack 830. That is, one voltage adjustment module 810 is connected with one battery pack 830, and each battery pack 830 is connected to one voltage adjustment module 810. The voltage adjustment module 810 controls the charging voltage input by the charging device to the corresponding battery pack 830. The battery pack 830 is connected with at least one load 840.

In another embodiment of the present invention, a charging management apparatus for multiple battery packs is provided. As shown in FIG. 11, the charging management apparatus 10 for multiple battery packs includes: an acquisition module 11 a determination module 12, a calculation module 13, a sending module 14 and charging module 15.

The acquisition module 11 is configured to acquire sampled temperatures, sampled voltages and sampled charging currents of various battery packs. The determination module 12 is configured to determine a target charging current of each battery pack according to the sampled temperature of each battery pack and the sampled voltage of each battery pack. The calculation module 13 is configured to calculate a total PI adjustment value according to the target charging currents and the sampled charging currents of the various battery packs. The sending module 14 is configured to send the total PI adjustment value to a charging device, to enable the charging device to adjust a total charging current according to the total PI adjustment value. The charging module 15 is configured to receive the total charging current, determine a charging current of each battery pack according to the sampled charging current of each battery pack and the total charging current, and determine a charging voltage of each battery pack according to the sampled voltage of each battery pack.

In other embodiments, the charging management apparatus for multiple battery packs further includes voltage adjustment modules, configured to control the charging voltage input to the battery pack. The voltage adjustment module corresponds one-to-one with the battery pack.

In the charging management apparatus 10 for multiple battery packs disclosed in this embodiment, the acquisition module 11, the determination module 12, the calculation module 13, the sending module 14 and the charging module 15 are used in combination, to implement the charging management method for multiple battery packs according to the embodiments above. The implementations and beneficial effects involved in the above-mentioned embodiments are equally applicable in this embodiment, and will not be repeated here.

It can be understood that the present application relates to an energy storage device, which includes a storage and one or more processors, where the storage stores a computer program thereon, and the computer program, when being executed, causes the one or more processors to implement the charging management method for multiple battery packs according to the present application.

It can be understood that the present application relates to a readable storage medium, storing a computer program, where the computer program, when being executed, causes the one or more processors to implement the charging management method for multiple battery packs according to the present application.

In the embodiments provided in the present application, it can be understood that the disclosed apparatus and method may be implemented in other ways. The apparatus embodiments described above are merely illustrative. For example, the flowcharts and structural diagrams in the accompanying drawings illustrate the architecture, functionality, and operation of possible implementations of devices, methods and computer program products according to various embodiments of the present application. In this regard, each box in a flowchart or a block diagram may represent a module, a program segment, or a part of code. The module, the program segment, or the part of code includes one or more executable instructions used for implementing designated logic functions. It should also be noted that in some alternative implementations, functions annotated in boxes may occur in a sequence different from that annotated in the accompanying drawing. For example, actually two boxes shown in succession can be performed basically in parallel, and sometimes the two boxes can be performed in a reverse sequence. This depends on the related functions. It should also be noted that each box in a block diagram and/or a flowchart and a combination of boxes in the block diagram and/or the flowchart may be implemented by using a dedicated hardware-based system configured to perform a specified function or operation, or may be implemented by using a combination of dedicated hardware and a computer instruction.

In addition, the functional modules or units in the various embodiments of the present application may be integrated into a separate part, or each of the modules may be present separately, or two or more modules may be integrated into separate part.

The functions, if implemented in the form of a software program module and sold or used as a stand-alone product, may be stored in a computer readable storage medium. Based on such an understanding, the essence of the technical solution of present application or part thereof contributing to the related art, or part of the technical solution can be implemented by a software product. The computer software product is stored in a storage medium and includes several instructions for instructing a computer device (which may be a smart phone, a personal computer, a server, a network device, or the like) to perform all or some of the steps of the methods described in the embodiments of the present application. The foregoing storage medium includes a USB disk, a movable hard disk, a Read Only Memory (ROM), a Random Access Memory (RAM), a magnetic disk, an optical disc and other media that can store program codes.

The foregoing descriptions are merely specific implementations of the present application, but are not intended to limit the scope of protection of the present application. Any variation or replacement readily figured out by a person skilled in the art within the technical scope disclosed in this application shall fall within the protection scope of the present application.

What is claimed is:

1. A charging management method for multiple battery packs, comprising:
acquiring sampled temperatures, sampled voltages and sampled charging currents of various battery packs;
determining a target charging current of each battery pack according to the sampled temperature of each battery pack and the sampled voltage of each battery pack;
calculating a difference between the sum of the target charging currents of the various battery packs and the sum of the sampled charging currents of the various battery packs, to obtain a total PI adjustment value;
sending the total PI adjustment value to a charging device, to enable the charging device to adjust a total charging current according to the total PI adjustment value; and
receiving the total charging current, determining a charging current of each battery pack according to the sampled charging current of each battery pack and the total charging current, and determining a charging voltage of each battery pack according to the sampled voltage of each battery pack.

2. The charging management method for multiple battery packs according to claim 1, wherein the step of acquiring sampled temperatures of various battery packs comprises:
acquiring battery core temperatures at a predetermined number of preset locations in an i-th battery pack, where 1≤i≤I, and I is the total number of the battery packs;
calculating a mean of the battery core temperatures at the predetermined number of preset locations; and
taking the mean as the sampled temperature of the i-th battery pack.

3. The charging management method for multiple battery packs according to claim 1, wherein the step of determining a target charging current of each battery pack according to the sampled temperature of each battery pack and the sampled voltage of each battery pack comprises:
determining a first charging current corresponding to the sampled temperature of an i-th battery pack according to a look-up table of the battery pack temperature and the target charging current, where 1≤i≤I, and I is the total number of the battery packs;
determining a second charging current corresponding to the sampled voltage of the i-th battery pack according to a look-up table of the battery pack voltage and the target charging current; and
taking a lower one of the first charging current and the second charging current as the target charging current of the i-th battery pack.

4. The charging management method for multiple battery packs according to claim 1, wherein the step of determining a charging current of each battery pack according to the sampled charging current of each battery pack and the total charging current comprises:
calculating a difference between the target charging current of an i-th battery pack and the sampled charging current of the i-th battery pack to determine a current difference of the i-th battery pack, where 1≤i≤I, and I is the total number of the battery packs;
determining a first target current adjustment value of the i-th battery pack according to the current differences of the various battery packs and the total PI adjustment value; and
charging the i-th battery pack with a charging current of the i-th battery pack that is the sum of the first target current adjustment value of the i-th battery pack and the sampled charging current of the i-th battery pack, where the sum of the charging currents of the various battery packs is equal to the total charging current.

5. The charging management method for multiple battery packs according to claim 1, wherein the step of determining a charging current of each battery pack according to the sampled charging current of each battery pack and the total charging current comprises:
acquiring a second target current adjustment value of an i-th battery pack, in which the second target current adjustment value of the i-th battery pack is preset, where 1≤i≤I, and I is the total number of the battery packs;
charging the i-th battery pack with a charging current of the i-th battery pack that is the sum of the second target current adjustment value of the i-th battery pack and the sampled charging current of the i-th battery pack, where the sum of the second target current adjustment values of the various battery packs is the total PI adjustment value, and the sum of the charging currents of the various battery packs is equal to the total charging current.

6. The charging management method for multiple battery packs according to claim 1, wherein the step of determining a charging voltage of each battery pack according to the sampled voltage of each battery pack comprises:
determining whether the sampled voltage of an i-th battery pack reaches a preset voltage threshold, where 1≤i≤I, and I is the total number of the battery packs;
when the sampled voltage of the i-th battery pack does not reach the voltage threshold, controlling a voltage difference between the charging voltage of the i-th battery pack and the sampled voltage of the i-th battery pack to fall within a preset voltage difference range; and
when the sampled voltage of the i-th battery pack reaches the voltage threshold, controlling the charging voltage of the i-th battery pack to be the sampled voltage of the i-th battery pack.

7. The charging management method for multiple battery packs according to claim 1, further comprising, before the step of sending the total PI adjustment value to a charging device, acquiring a load current of a load to which each battery pack is correspondingly connected, wherein the step of sending the total PI adjustment value to a charging device comprises:
summing the load currents of the various battery packs and the total PI adjustment value, and updating the total PI adjustment value with the summed value; and
sending the updated total PI adjustment value to the charging device.

8. A charging management apparatus for multiple battery packs, comprising:
an acquisition module, configured to acquire sampled temperatures, sampled voltages and sampled charging currents of various battery packs;
a determination module, configured to determine a target charging current of each battery pack according to the sampled temperature of each battery pack and the sampled voltage of each battery pack;
a calculation module, configured to calculate a total PI adjustment value according to the target charging currents and the sampled charging currents of the various battery packs;
a sending module, configured to send the total PI adjustment value to a charging device, to enable the charging device to adjust a total charging current according to the total PI adjustment value; and
a charging module, configured to receive the total charging current, determine a charging current of each battery pack according to the sampled charging current of each battery pack and the total charging current, and determine a charging voltage of each battery pack according to the sampled voltage of each battery pack.

9. The charging management apparatus for multiple battery packs according to claim 8, further comprising:
a voltage adjustment module, configured to control the charging voltage input to the battery pack.

10. The charging management apparatus for multiple battery packs according to claim 9, wherein the voltage adjustment module corresponds one-to-one with the battery pack.

11. An energy storage device, comprising a storage and one or more processors, wherein the storage stores a computer program thereon, and the computer program, when being executed, cause the one or more processors to implement the charging management method for the multiple battery packs according to claim 1.
